(19) United States
(12) Patent Application Publication
(10) Pub. No.: US 2025/0113684 A1
(43) Pub. Date: Apr. 3, 2025

(54) LED INCANDESCENT LAMP HAVING PAINT COATING

(71) Applicant: SAVANT TECHNOLOGIES LLC, East Cleveland, OH (US)

(72) Inventors: Kun XIAO, Shanghai (CN); Jie GAO, Shanghai (CN); Xuda LI, Shanghai (CN)

(73) Assignee: SAVANT TECHNOLOGIES LLC, East Cleveland, OH (US)

(21) Appl. No.: 18/818,349

(22) Filed: Aug. 28, 2024

(30) Foreign Application Priority Data
Sep. 19, 2023 (CN) 202311216800.2

(51) Int. Cl. H10H 29/24; F21K 9/232; F21Y 103/10; H01L 25/075; H10H 20/851; H10H 20/854

(52) U.S. Cl. CPC H10H 29/24; F21K 9/232; H01L 25/0753; H10H 20/8512; H10H 20/854; F21Y 2103/10

(57) ABSTRACT

Provided is a light emitting diode (LED) light source and an LED incandescent lamp with a coating cladding layer that includes a LED light source, which includes one or more LED chips coated with a phosphor material underlying layer exhibiting a colored appearance; and an outer coating having a coating composition, the coating composition includes a solvent, a binder, and a pigment. The LED light source having a small thickness, aesthetic appearance, and high light transmittance.

### CROSS-REFERENCE TO RELATED APPLICATION

This application claims priority to Chinese Patent Application Serial Number 202311216800.2, filed Sep. 19, 2023, which is herein incorporated by reference.

### DESCRIPTION

### Technical Field

The present invention relates to a LED incandescent lamp with a coating cladding layer, in particular to a LED light source with an outer coating comprising a coating composition.

### Background

Lighting devices, such as lamps, illuminators, decorative or general-purpose lamps, electronic tubes or other light-emitting devices, or other lighting systems, typically include one or more light-emitting diode (LED) light sources (filaments), which are composed of a linear series of LED chips arranged on a transparent substrate, and supported or maintained in a housing to provide the appearance of an incandescent lamp. The light source (filament) is typically constructed from InGaN blue light-emitting LED chips carried on essentially linear glass or sapphire substrates, and covered or encapsulated with a mixture of silicone and phosphor. Typically, encapsulating mixtures can have yellow or other colors when they are not illuminated. An exemplary LED filament 100 with a yellow covering is shown in FIG. 1A. FIG. 1B and FIG. 1C show the LED filaments exhibiting a colored appearance that are integrated into different types of lighting devices. Due to opposition to yellow when not illuminated (especially when used for decorative and general-purpose lamps), the appearance of the filament may be unfavorable. The actual light sources of LED products on the market generally use silicone as the raw material for making the outer coating, resulting in a larger coating thickness, and after the color is changed, the increase in thickness will in turn affect the aesthetics.

### SUMMARY

The main object of the present invention is to provide a LED incandescent lamp and a LED light source with an outer coating and having a small thickness, aesthetic appearance, and high light transmittance, so as to solve the problems in the prior art.

In order to achieve the above object, in one aspect, the present invention provides a LED light source, comprising one or more LED chips coated with a phosphor material underlying layer exhibiting a colored appearance; and an outer coating comprising a coating composition, wherein the coating composition includes a solvent, a binder, and a pigment, and the outer coating gives the LED chips a color appearance different from the underlying material in a power-off state.

In order to achieve the above object, in another aspect, the present invention also provides a lighting device, which includes one or more LED light sources, wherein the LED light source includes: a substrate, one or more LED chips formed on the substrate, with the LED chip being coated with a phosphor material underlying layer exhibiting a colored appearance; and an outer coating formed on the phosphor material underlying layer, wherein the outer coating includes a coating composition, and the coating composition comprises a solvent, a binder, and a pigment.

Further, the solvent is an organic solvent, and the organic solvent includes one or more of n-butyl acetate, ethyl acetate, and acetone.

Further, the binder includes one or more of alkyd emulsion, vinyl acrylic resin and styrenated acrylic resin.

Further, the pigment includes one or more of titanium dioxide, lutetium oxide, yttrium oxide, silicon dioxide, alumina, zirconia, quartz, and glass powder, and the pigment gives the LED chips a white appearance in a power-off state.

Further, the coating composition also includes an additive.

Further, the additive includes one or more of a surfactant, an antimicrobial agent, and a defoaming agent.

Further, the solvent is present in an amount ranging from 28 wt % to 44 wt % based on the total weight of the coating composition.

Further, the pigment is present in an amount ranging from 0.5 wt % to 23 wt % based on the total weight of the coating composition.

Further, the thickness of the outer coating ranges from 0.1 mm to 0.4 mm.

Further, the total thickness of the LED light source ranges from 1.2 mm to 1.8 mm.

Yet another aspect of the present invention provides a use of a coating composition comprising a solvent, a binder, and a pigment in the preparation of an outer coating of a LED light source, wherein the LED light source includes one or more LED chips coated with a phosphor material underlying layer exhibiting a colored appearance; and the outer coating, which gives the LED chips a color appearance different from the underlying material in a power-off state.

Further, the phosphor material underlying layer exhibits a yellow, orange, or red appearance.

Further, the phosphor material underlying layer includes a doped phosphor with a fluoride host.

Further, the phosphor material underlying layer includes a phosphor material, which comprises a PFS phosphor (K₂SiF₆:Mn⁴⁺).

Further, the phosphor material underlying layer includes phosphors that emit yellow or yellow-green light, such as garnet phosphors.

Further, the phosphor material underlying layer includes phosphors that emit red light, such as Eu²⁺ red nitride phosphors.

Further, the phosphor material underlying layer includes an absorbent.

Further, the phosphor material underlying layer includes a resin material.

An embodiment of the present invention provides a LED light source that includes
one or more LED chips coated with a phosphor material underlying layer exhibiting a colored appearance; and
an outer coating comprising a coating composition, wherein the coating composition comprises a solvent, a binder, and a pigment, and the outer coating gives the LED chips a color appearance different from the underlying material in a power-off state.

The solvent is an organic solvent, and the organic solvent comprises one or more of n-butyl acetate, ethyl acetate, and acetone.

The binder comprises one or more of alkyd emulsion, vinyl acrylic resin and styrenated acrylic resin.

The pigment comprises one or more of titanium dioxide, lutetium oxide, yttrium oxide, silicon dioxide, alumina, zirconia, quartz, and glass powder, and the pigment gives the LED chips a white appearance in a power-off state.

The coating composition further comprises an additive.

The additive comprises one or more of a surfactant, an antimicrobial agent, and a defoaming agent.

The solvent is present in an amount ranging from 28 wt % to 44 wt % based on the total weight of the coating composition.

The pigment is present in an amount ranging from 0.5 wt % to 23 wt % based on the total weight of the coating composition.

The thickness of the outer coating ranges from 0.1 mm to 0.4 mm.

The total thickness of the LED light source ranges from 1.2 mm to 1.8 mm.

Another embodiment of the present invention provides a lighting device comprising one or more LED light sources, wherein the LED light source comprises:
a substrate,
one or more LED chips formed on the substrate, with the LED chip being coated with a phosphor material underlying layer exhibiting a colored appearance; and
an outer coating formed on the phosphor material underlying layer, wherein the outer coating comprises a coating composition, the coating composition comprises a solvent, a binder, and a pigment, and the outer coating gives the LED chips a color appearance different from the underlying material in a power-off state.

The solvent is an organic solvent, and the organic solvent comprises one or more of n-butyl acetate, ethyl acetate, and acetone.

The binder comprises one or more of alkyd emulsion, vinyl acrylic resin and styrenated acrylic resin.

The pigment comprises one or more of titanium dioxide, lutetium oxide, yttrium oxide, silicon dioxide, alumina, zirconia, quartz, and glass powder, and the pigment gives the LED chips a white appearance in a power-off state.

The coating composition further comprises an additive.

The additive comprises one or more of a surfactant, an antimicrobial agent, and a defoaming agent.

The solvent is present in an amount ranging from 28 wt % to 44 wt % based on the total weight of the coating composition.

The pigment is present in an amount ranging from 0.5 wt % to 23 wt % based on the total weight of the coating composition.

The thickness of the outer coating ranges from 0.1 mm to 0.4 mm, and the total thickness of the LED light source ranges from 1.2 mm to 1.8 mm.

Yet another embodiment of the present invention provides use of a coating composition comprising a solvent, a binder, and a pigment in the preparation of an outer coating of a LED light source, wherein the LED light source comprises one or more LED chips coated with a phosphor material underlying layer exhibiting a colored appearance; and the outer coating, which gives the LED chips a color appearance different from the underlying material in a power-off state.

By applying the technical solution of the present invention, the thickness of the outer coating can be reduced, such as up to a thickness of only about 0.1 mm to about 0.4 mm, by using the outer coating of a specific coating composition comprising a solvent, a binder, and a pigment of the present invention, which reduces the consumption of raw materials, lowers the cost and improves the production efficiency. By providing a specific outer coating of the present invention, the appearance of the LED light source is changed from a colored appearance to a white appearance, thereby improving the aesthetic appearance of the LED light source. In addition, by applying the specific outer coating of the present invention, the light transmittance of the LED light source can also be improved, and the loss of luminous flux (lumen) can be reduced.

### BRIEF DESCRIPTION OF THE DRAWINGS

The accompanying drawings of the description, which form a part of the application, are used to provide a further understanding of the invention. The illustrative examples and their descriptions of the invention are used to explain the invention, and do not constitute an improper limitation thereto. In the accompanying drawings:

FIGS. 1A to 1C show a schematic diagram of the LED filaments with colored coverings of various embodiments in the prior art.

FIG. 2 shows an exemplary LED light source with a white appearance according to an embodiment of the present disclosure.

FIG. 3 shows a schematic diagram of a LED light source coated with an outer coating on the phosphor material underlying layer according to an embodiment of the present disclosure.

FIG. 4 shows a cross-sectional view of the LED light source as shown in FIG. 3.

FIG. 5A shows exemplary color dots of a LED light source without an outer coating and a LED light source with different thicknesses of outer coatings according to an embodiment of the present disclosure.

FIG. 5B shows a schematic diagram of the color dot offset amplitude in Commission Internationale de l'Eclairage (CIE) 1931 color space of the corresponding LED light source as the thickness of the outer coating changes, according to an embodiment of the present disclosure.

FIG. 5C shows a schematic diagram of the color temperature offset amplitude of the corresponding LED light source as the thickness of the outer coating changes, according to an embodiment of the present disclosure.

FIG. 5D shows a schematic diagram of change in luminous flux (Relative lumen) of the corresponding LED light source as the thickness of the outer coating changes, according to an embodiment of the present disclosure.

FIG. 6A shows exemplary color dots of a LED light source without an outer coating and a LED light source with different thicknesses of outer coatings according to another embodiment of the present disclosure.

FIG. 6B shows a schematic diagram of the color dot offset amplitude in CIE 1931 color space of the corresponding LED light source as the thickness of the outer coating changes, according to another embodiment of the present disclosure.

FIG. 6C shows a schematic diagram of the color temperature offset amplitude of the corresponding LED light source as the thickness of the outer coating changes, according to another embodiment of the present disclosure.

FIG. 6D shows a schematic diagram of change in luminous flux (Relative lumen) of the corresponding LED light source as the thickness of the outer coating changes, according to another embodiment of the present disclosure.

FIG. 7 shows a schematic diagram of the coating results of a coating composition prepared using water-silicone as a solvent.

FIG. 8 shows a comparative diagram of LED light sources made of the coating compositions based on water-silicone and n-butyl acetate as solvents, respectively, and

FIG. 9 shows the LED light source prepared when using n-butyl acetate as a solvent to prepare a coating composition.

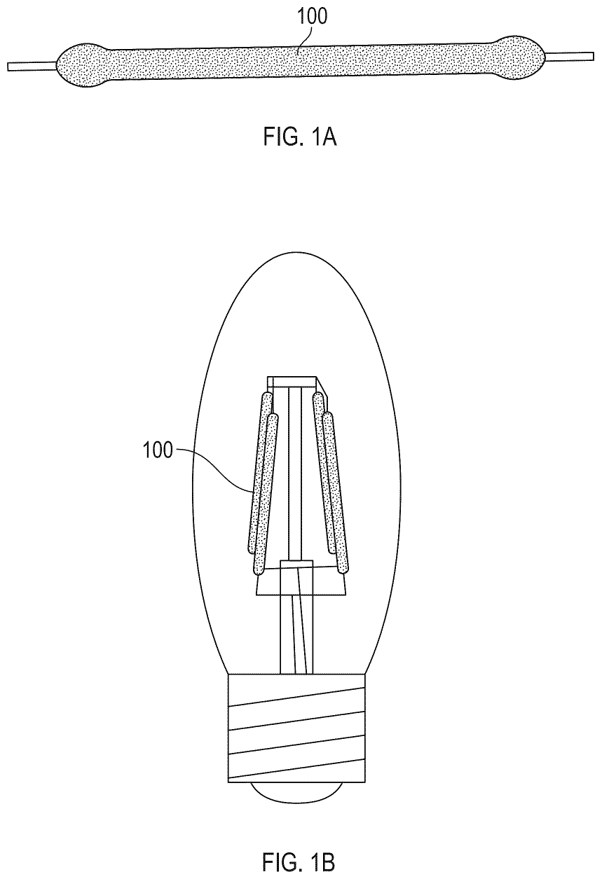

### DETAILED DESCRIPTION OF THE EMBODIMENTS

It should be noted that the examples and features in the examples in the application can be combined with each other without conflicting. The present invention will be described in detail below in combination with embodiments.

Targeting at the shortcomings in the prior art mentioned above, a specific embodiment of the present disclosure provides a LED light source, comprising one or more LED chips coated with a phosphor material underlying layer exhibiting a colored appearance; and an outer coating comprising a coating composition, wherein the coating composition includes a solvent, a binder, and a pigment, and the outer coating gives the LED chips a color appearance different from the underlying material in a power-off state.

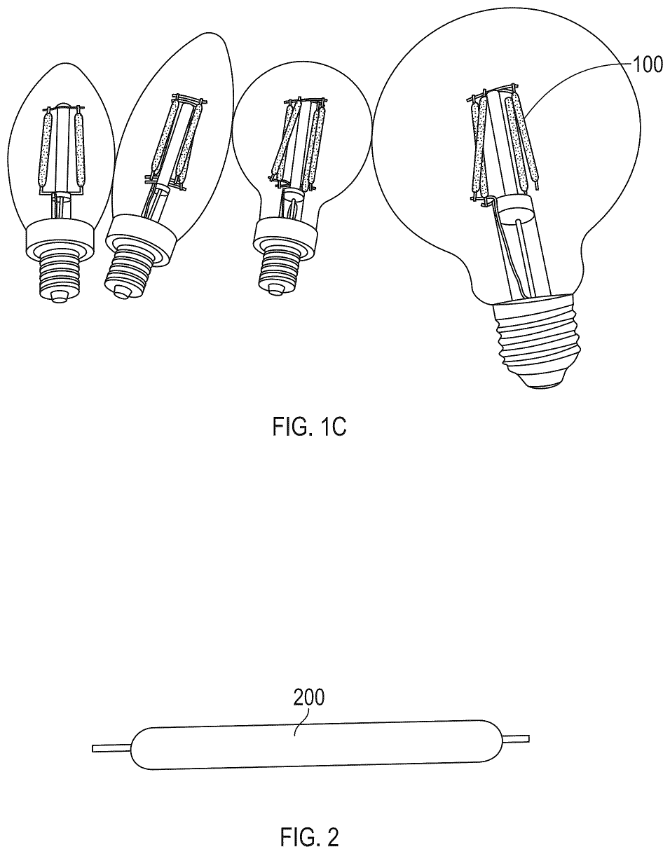

As mentioned above, the LED light source with an outer coating in the prior art has problems of large thickness, poor aesthetics, and low light transmittance. In view of the above problems, the present disclosure provides a LED light source with an outer coating, which can provide a LED light source with an outer coating and significantly reduced thickness, an appearance exhibiting excellent whiteness and high light transmittance by using an outer coating comprising a coating composition containing a solvent, a binder, and a pigment. The pigments in the coating composition can provide a white appearance for the LED light source with an outer coating of the present disclosure and absorb light to the minimum extent. The binder in the coating composition can serve as a carrier to load pigments, the pigment particles are evenly dispersed in the binder, and the binder can fully bond the pigment particles present in the outer coating and make the outer coating fully bond to the phosphor material underlying layer, which improves the white appearance of the LED light source while improving the light transmission. The solvent in the coating composition can dissolve the binder and pigment, thereby improving the uniformity of the binder and pigment, effectively reducing the dynamic viscosity of the coating composition, so that the coating composition can be coated on the LED light source with an outer coating of the present disclosure in a thinner and more uniform thickness, without damaging the white appearance and light transmittance of the LED light source with an outer coating. An exemplary LED light source 200 with an outer coating according to an embodiment of the present disclosure is shown in FIG. 2.

The so-called “underlying layer” usually refers to the phosphor material layer that exhibits a colored appearance, which is located below the outer coating. That is to say, the underlying layer is located between the outer coating and the LED chip. There may or may not be an intermediate layer between the LED chip and the underlying layer, and/or between the underlying layer and the outer coating. Typically, in this disclosure, references to the “colored” or “white” appearance involve the color of the material when it is not excited by the excitation wavelength. For example, if the underlying layer only contains a phosphor powders that are white when viewed under non-excited visible light, they will not be considered “colored”, even if they can emit color when excited.

Another specific embodiment of the present disclosure provides a lighting device, which includes one or more LED light sources. The LED light source includes: a substrate, one or more LED chips formed on the substrate, with the LED chip being coated with a phosphor material underlying layer exhibiting a colored appearance; and an outer coating formed on the phosphor material underlying layer, wherein the outer coating includes a coating composition, the coating composition comprises a solvent, a binder, and a pigment, and the outer coating gives the LED chips a color appearance different from the underlying material in a power-off state.

As mentioned above, in the lighting device according to the present invention, a specific coating composition according to the present invention is used as the outer coating of the LED light source, and the pigments in the coating composition can provide a white appearance for the lighting device of the present disclosure and absorb light to the minimum extent. The binder in the coating composition can serve as a carrier to load pigments, the pigment particles are evenly dispersed in the binder, and the binder can fully bond the pigment particles present in the outer coating and make the outer coating fully bond to the phosphor material underlying layer, which improves the white appearance of the lighting device while improving the light transmission. The solvent in the coating composition can dissolve the binder and pigment, thereby improving the uniformity of the binder and pigment, effectively reducing the dynamic viscosity of the coating composition, so that the coating composition can be coated on the LED light source with an outer coating of the present disclosure in a thinner and more uniform thickness, without damaging the white appearance and light transmittance of the LED light source with an outer coating.

In some examples, the light source may include one or more of filaments, lamp beads, light strips, and light sheets.

In some examples, the solvent is an organic solvent, and the organic solvent includes one or more of n-butyl acetate, ethyl acetate, and acetone. For example, the solvent includes n-butyl acetate, ethyl acetate, acetone, or a combination thereof. In the prior art, water or a mixture of water and silicone is used as a solvent, but when the above is used as a solvent, the coating has uneven compositions and the adhesion is poor. Compared to the solvents in the prior art, the use of solvents within the scope of the present disclosure can further improve the dispersion uniformity of the binders and pigment particles in the coating composition, further reduce the dynamic viscosity of the coating composition, and improve the adhesion of the coating composition to the phosphor material underlying layer. Therefore, the coating composition can be more effectively coated on the LED light source in a uniform thin layer form. Moreover, the use of solvents within the scope of the present disclosure can further improve the white appearance of LED light source with an outer coating and increase the light transmission.

In some examples, the binder includes one or more of alkyd emulsion, vinyl acrylic resin and styrenated acrylic resin. For example, the binder includes alkyd emulsion, vinyl acrylic resin and styrenated acrylic resin, or a combination thereof. Preferably, the binder includes alkyd emulsion or vinyl acrylic resin. More preferably, the binder includes alkyd emulsion. Compared to the binders such as silicone resin components, etc. in the prior art, the use of binders within the scope of the present disclosure can further improve the dispersion uniformity of pigment particles and the adhesion to pigment particles, and can further improve the adhesion of the coating composition to the phosphor material underlying layer, further reducing the dynamic viscosity of the coating composition and the thickness of the outer coating.

In some examples, the pigment includes one or more of titanium dioxide, lutetium oxide, yttrium oxide, silicon dioxide, alumina, zirconia, quartz, and glass powder. For example, the pigment includes titanium dioxide, lutetium oxide, yttrium oxide, silicon dioxide, alumina, zirconia, quartz, glass powder, or a combination thereof. The use of pigments within the scope of the present disclosure further improves the whiteness of the LED light source with an outer coating, further reduces light absorption, thereby providing a more aesthetically pleasing white appearance for the LED chips in a power-off state.

In some examples, the coating composition also includes an additive. By adding an additive to the coating composition, the required properties of the coating composition can be further improved. For example, the additive includes one or more of a surfactant, an antimicrobial agent, and a defoaming agent. By way of an example, the additive includes a surfactant, an antimicrobial agent, a defoaming agent, or a combination thereof.

In some examples, the solvent is present in an amount ranging from 28 wt % to 44 wt % based on the total weight of the coating composition. For example, the solvent is present in an amount of 28 wt %, 29 wt %, 30 wt %, 31 wt %, 32 wt %, 33 wt %, 34 wt %, 35 wt %, 36 wt %, 37 wt %, 38 wt %, 39 wt %, 40 wt %, 41 wt %, 42 wt %, 43 wt %, and 44 wt %, etc., based on the total weight of the coating composition. When the amount of solvent is within the scope of the present disclosure, the dynamic viscosity of the coating composition can be further reduced, and the coating composition can be coated in a thinner thickness on the LED light source with an outer coating. At the same time, the white appearance and light transmittance of the LED light source with an outer coating can also be further improved.

In some examples, the pigment is present in an amount ranging from 0.5 wt % to 23 wt % based on the total weight of the coating composition. For example, the pigment is present in an amount of 0.5 wt %, 1.0 wt %, 1.5 wt %, 2.0 wt %, 3.0 wt %, 4.0 wt %, 5.0 wt %, 6.0 wt %, 7.0 wt %, 8.0 wt %, 9.0 wt %, 10.0 wt %, 12.0 wt %, 14.0 wt %, 16.0 wt %, 18.0 wt %, 20.0 wt %, 21.0 wt %, 22.0 wt %, and 23.0 wt %, etc., based on the total weight of the coating composition. Preferably, the pigment is present in an amount ranging from 10.0 wt % to 23.0 wt %. More preferably, the pigment is present in an amount ranging from 16.0 wt % to 23.0 wt %. Most preferably, the pigment is present in an amount ranging from 21.0 wt % to 23.0 wt %. When the amount of pigment is within the scope of the present disclosure, the pigment can further reduce light absorption and further improve the white appearance of the LED light source with an outer coating.

In some examples, the thickness of the outer coating ranges from 0.1 mm to 0.4 mm. For example, the thickness of the outer coating is 0.1 mm, 0.15 mm, 0.2 mm, 0.25 mm, 0.3 mm, 0.35 mm, and 0.4 mm, etc. The thickness of the outer coating is within the scope of the present disclosure, which can further reduce the thickness of the outer coating and the total thickness of the LED light source with an outer coating, further reduce the consumption of raw materials and further reduce the cost, thereby improving the production efficiency.

In some examples, the total thickness of the LED light source ranges from 1.2 mm to 1.8 mm. For example, the total thickness of the LED light source is 1.2 mm, 1.3 mm, 1.4 mm, 1.5 mm, 1.6 mm, 1.7 mm, and 1.8 mm, etc. The total thickness of LED light source within the scope of the present disclosure can further reduce the consumption of raw materials, be more cost-effective, and can further improve the aesthetic appearance of the LED light source with an outer coating.

In some examples, the phosphor material underlying layer exhibits a yellow, orange, or red appearance. Specifically, the phosphor material underlying layer can include a doped phosphor with a fluoride host. For example, the phosphor material underlying layer can include a phosphor material, which comprises a PFS phosphor (K₂SiF₆:Mn⁴⁺). In addition, the phosphor material underlying layer can include phosphors that emit yellow or yellow-green light, such as garnet phosphors, or can include phosphors that emit red light, such as Eu²⁺ red nitride phosphors.

In some examples, the phosphor material underlying layer can include an absorbent and/or a resin material.

The outer coating can be applied to a conventional LED light source through various processes, such as spray coating, moulding, dip coating, applying through automatic or manual fluid dispensers, or any other suitable applying processes.

The application will be further described in detail below in combination with specific examples, which cannot be understood as limiting the scope of protection claimed in the application.

### Example 1

A substrate and LED chips were provided, the LED chips were mounted on the substrate to form a LED tube core with LED chips provided on the substrate. A phosphor material underlying layer (using an activated composite fluoride phosphor containing Mn⁴⁺(K₂SiF₆:Mn⁴⁺)) was provided on the LED tube core. After applying the phosphor material underlying layer, the total thickness of the LED tube core was measured to be 1 mm (i.e. a LED light source without an outer coating).

The alkyd emulsion, n-butyl acetate and pigment (lutetium oxide, yttrium oxide, silicon dioxide and titanium dioxide) were evenly mixed in a mixer, and a surfactant (sodium dodecylbenzene sulfonate) was added thereto, thus forming an initial coating composition (A). The weight percentage of the alkyd emulsion was 31 wt %, the weight percentage of the n-butyl acetate was 28 wt %, the weight percentages of the lutetium oxide, yttrium oxide, silicon dioxide, and titanium dioxide were 0.5 wt %, 11.5 wt %, 9.5 wt %, and 0.5 wt %, respectively, and the weight percentage of the surfactant was 19 wt %, based on the total weight of the initial coating composition (A).

The dynamic viscosities of each coating composition were measured with a T-4 cup viscometer, respectively. The n-butyl acetate and titanium dioxide were further added to the initial coating composition (A) in accordance with the proportions shown in Table 1 to form a coating composition (B) (based on the total weight of the initial coating composition (A), 16 wt % of n-butyl acetate and 0.5 wt % of titanium dioxide were added) and a coating composition (C) (based on the total weight of the initial coating composition (A), 9 wt % of n-butyl acetate and 0.5 wt % of titanium dioxide were added).

The coating compositions obtained above were each applied to the above phosphor material underlying layers to form an outer coating of each coating composition on the phosphor material underlying layers.

TABLE 1

| | Dynamic viscosity |
|---|---|
| Composition of Coating Composition | (mm²/s) |
| Initial coating composition (A) | 550 |
| Coating composition (B) | 200 |
| Coating composition (C) | 300 |

It can be seen from the results in Table 1 that the dynamic viscosity of the initial coating composition (A) is 550 mm²/s. Further addition of a solvent and a pigment can adjust the dynamic viscosity of the coating composition, so that the coating compositions (B) and (C) can have a reduced dynamic viscosity.

Further, the correlated color temperature (CCT) and color dots in CIE 1931 color space of LEDs with and without the outer coating of the present invention were determined. In Table 2 below, sample 1 and sample 2 represent the results of determination of the correlated color temperature (CCT) and the color dots in CIE 1931 color space on the LED tube core before the outer coating of the present invention is applied. Sample 3 represents the result of determination of the correlated color temperature (CCT) and the color dots in CIE 1931 color space on the LED light source after applying the coating composition (C) on the basis of the LED tube core of sample 2. The correlated color temperature offset and color dot offset of the samples were calculated. The determination and calculation results are shown in Table 2 below.

TABLE 2

| | | Luminous | Correlated | | | | |
|---|---|---|---|---|---|---|---|
| | Composition of | flux | color | | | | |
| Sample | Coating | (lumen, | temperature | | | | |
| No. | Composition | lm) | CCT (K) | CCX | CCY | Ra | R9 |
| 1 | — | 170 | 2700 | 0.4578 | 0.4101 | 80 | 0 |
| 2* | — | 185 | 4156 | 0.3749 | 0.3773 | 83.9 | 14.2 |
| 3 | Coating | 152 | 2831 | 0.4558 | 0.4200 | 80.8 | 0 |
| | composition | | | | | | |
| | (C) | | | | | | |
| 4 | Difference | 18(10.5%) | 131 | 0.0020 | 0.0099 | 0.8 | 0 |
| | between | | | | | | |
| | sample 1 and | | | | | | |
| | sample 3 | | | | | | |
| 5 | Difference | 33(17.8%) | 1325 | 0.0809 | 0.0427 | 3.1 | 14.1 |
| | between | | | | | | |
| | sample 2 and | | | | | | |
| | sample 3 | | | | | | |

*Sample 1 and sample 2 represent different color temperatures of LED light sources due to different compositions of the phosphor material underlying layer

From the comparison between sample 1 and sample 2 in above Table 2, it can be seen that when adjusting the fluorescent powder content of the phosphor underlying layer to exhibit different correlated color temperatures (sample 1: 2700 K; sample 2: 4156 K) (absence of outer coating on the LED tube core), the corresponding luminous fluxes (lumens) of different correlated color temperatures are different. Overall, in the case of the same composition, the lower the correlated color temperature, the lower the luminous flux (lumen).

As shown by sample 3 in Table 2, after applying an outer coating (coating composition (C)) to the LED tube core of sample 2, the outer coating affects the luminescent spectrum of the LED light source, so that the correlated color temperature is significantly reduced, and the color dots in CIE 1931 color space also undergo significant offset.

### Example 2

A substrate and LED chips were provided, the LED chips were mounted on the substrate to form a LED tube core with LED chips provided on the substrate. A phosphor material underlying layer (using an activated composite fluoride phosphor containing Mn⁴⁺(K₂SiF₆:Mn⁴⁺)) was provided on the LED tube core. After applying the phosphor material underlying layer, the total thickness of the LED tube core was measured to be 1 mm (i.e. a LED light source without an outer coating).

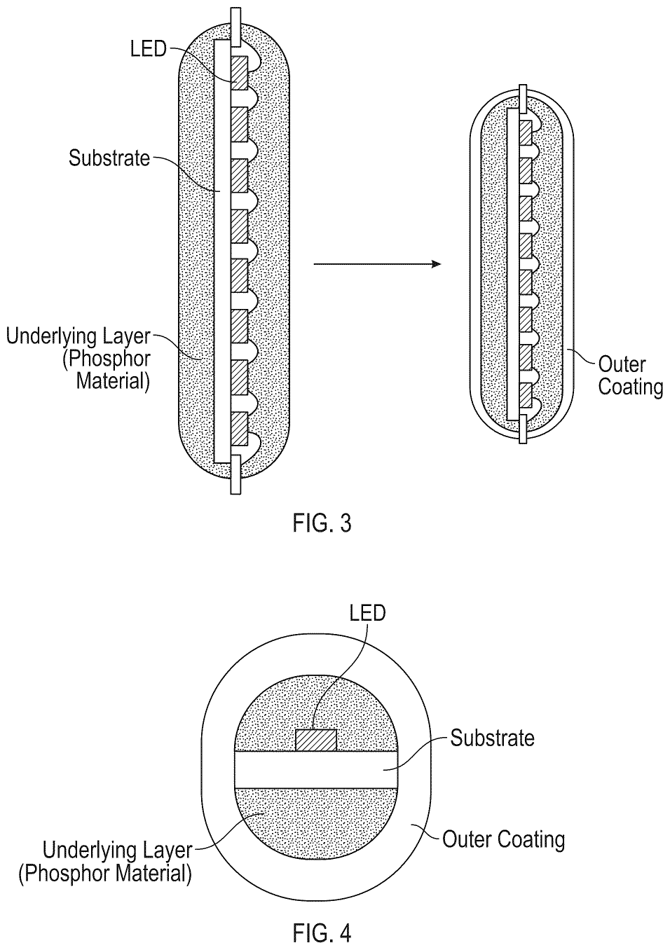

The coating composition (C) prepared in Example 1 was used as the composition of the outer coating for the coating of LED tube core. As shown in FIGS. 3 and 4, the coating composition was spray coated onto the phosphor material underlying layer, forming an outer coating of the coating composition (C) on the phosphor material underlying layer.

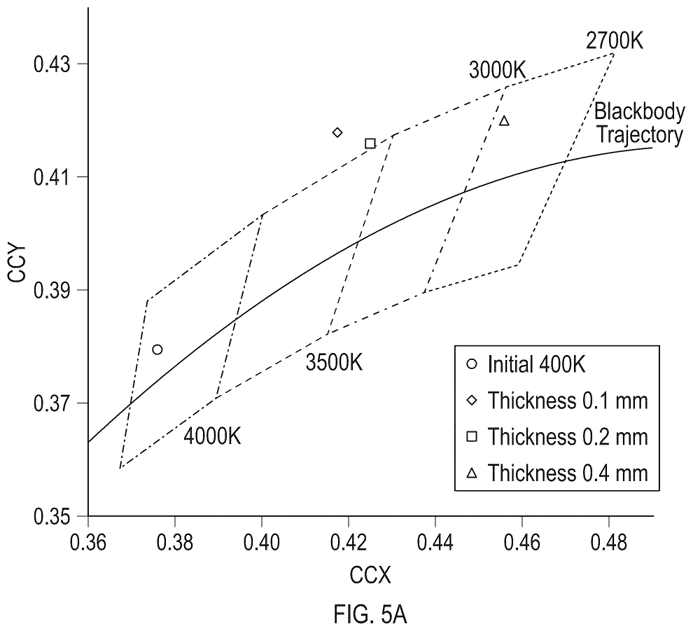

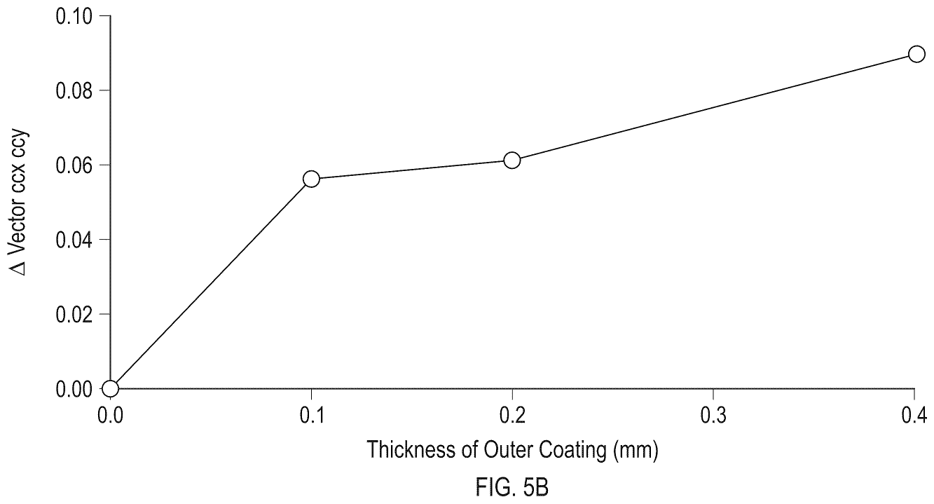

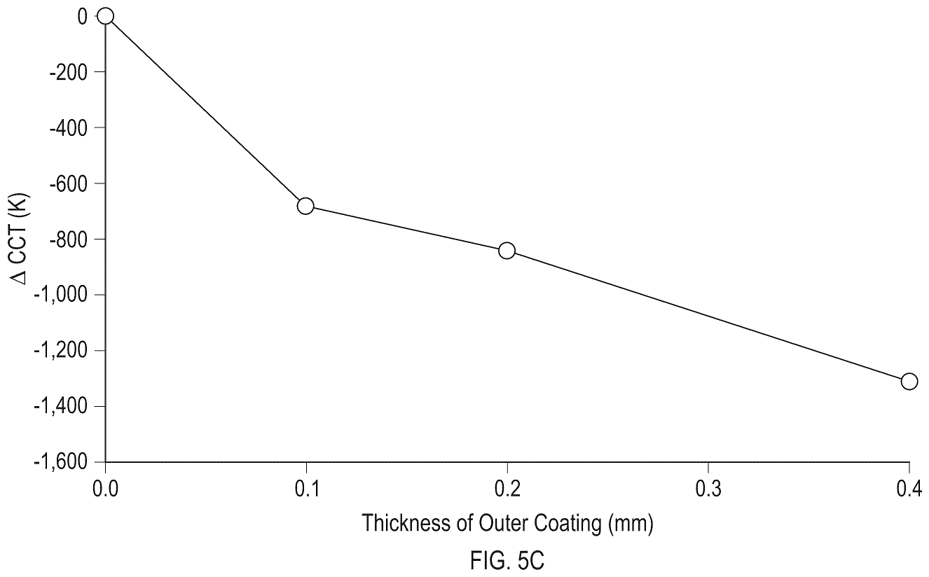

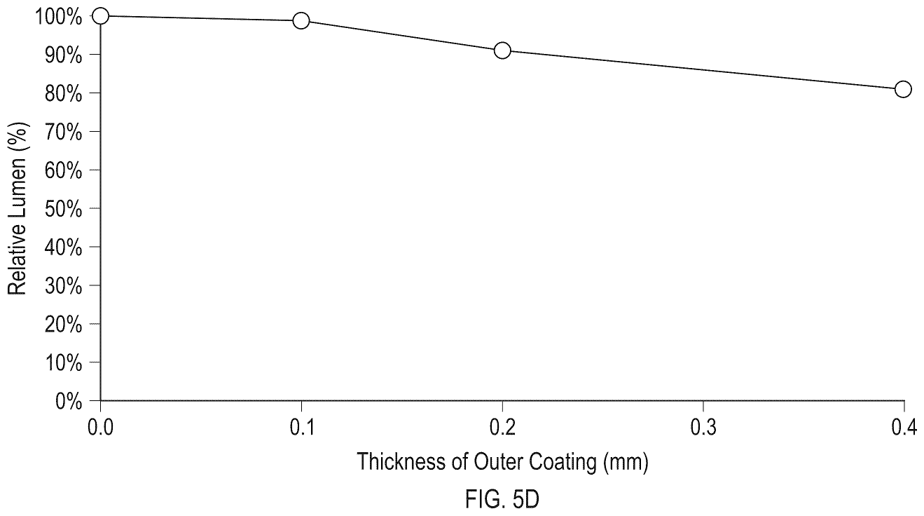

Referring to the attached drawings, FIG. 5A shows exemplary color dots of a LED light source without an outer coating and a LED light source with different thicknesses of outer coatings, where filled circles represent color dots of a LED light source without an outer coating; filled rhombuses represent the color dots of a LED light source with an outer coating having a thickness of 0.1 mm; filled squares represent the color dots of a LED light source with an outer coating having a thickness of 0.2 mm; and filled triangles represent the color dots of a LED light source with an outer coating having a thickness of 0.4 mm. The application of the outer coating causes the color dots to move over the blackbody trajectory and to a lower correlated color temperature (CCT), wherein the thicker the outer coating, the more significant the offset amplitudes of the color dots and color temperature.

FIG. 5B shows the color dot offset amplitude in CIE 1931 color space of the corresponding LED light source with an outer coating as the thickness of the outer coating changes. As the diameter or thickness of the outer coating increases, i.e. increasing from 0.1 mm to 0.4 mm, the color dot offset amplitude significantly increases.

FIG. 5C shows the color temperature offset amplitude of the corresponding LED light source with an outer coating as the thickness of the outer coating changes. As the diameter or thickness of the outer coating increases, i.e. increasing from 0.1 mm to 0.4 mm, there is a significant offset in the correlated color temperature (CCT).

FIG. 5D shows the changes in luminous flux of the corresponding LED light source with an outer coating as the thickness of the outer coating changes. As the diameter or thickness of the outer coating increases, i.e., increasing from 0.1 mm to 0.4 mm, the luminous flux (lumen) decreases, resulting in increased optical loss. An increase in the diameter or thickness of the outer coating can cause light diffusion and much greater optical loss.

### Example 3

A LED light source with an outer coating was provided in the same way as example 2, except that the initial coating composition (A) was used instead of the coating composition (C).

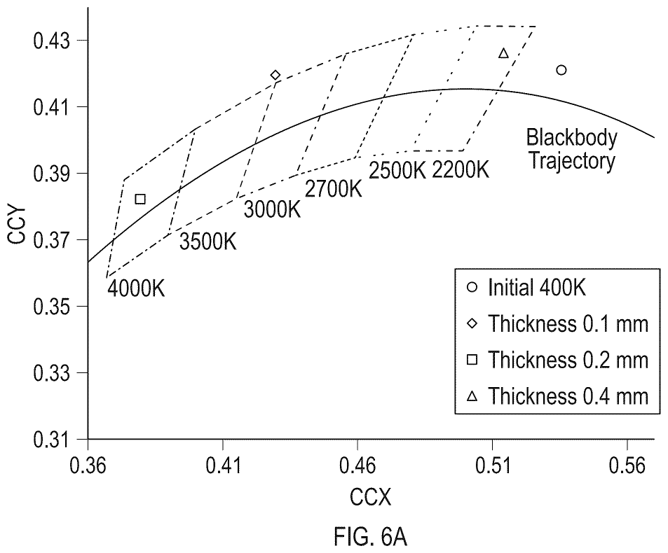

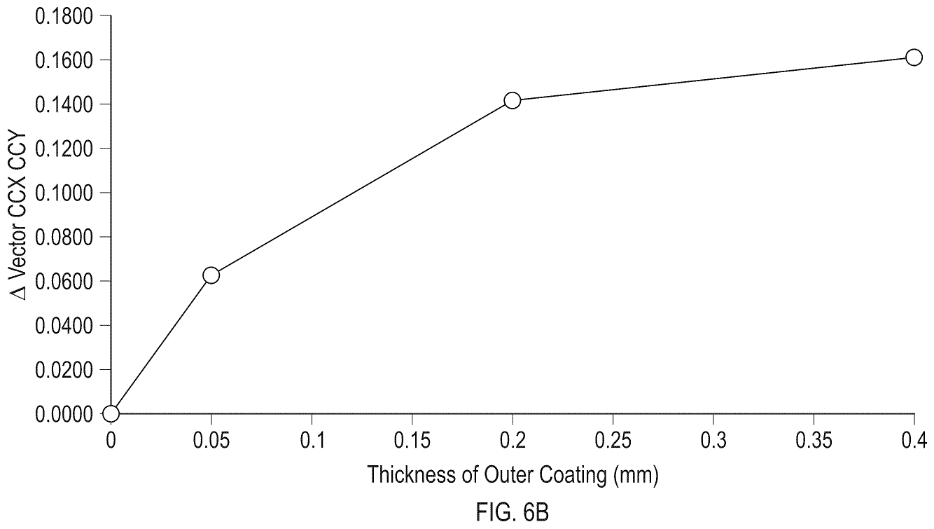

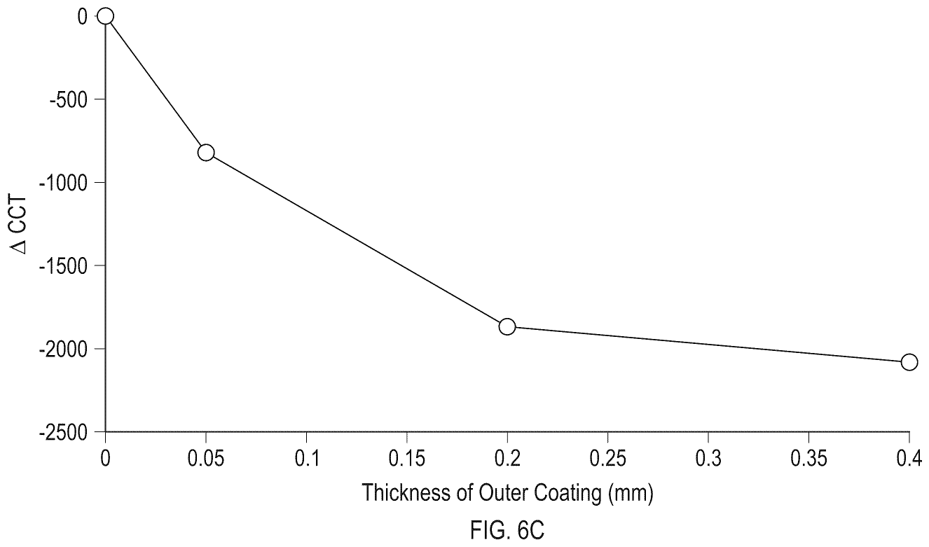

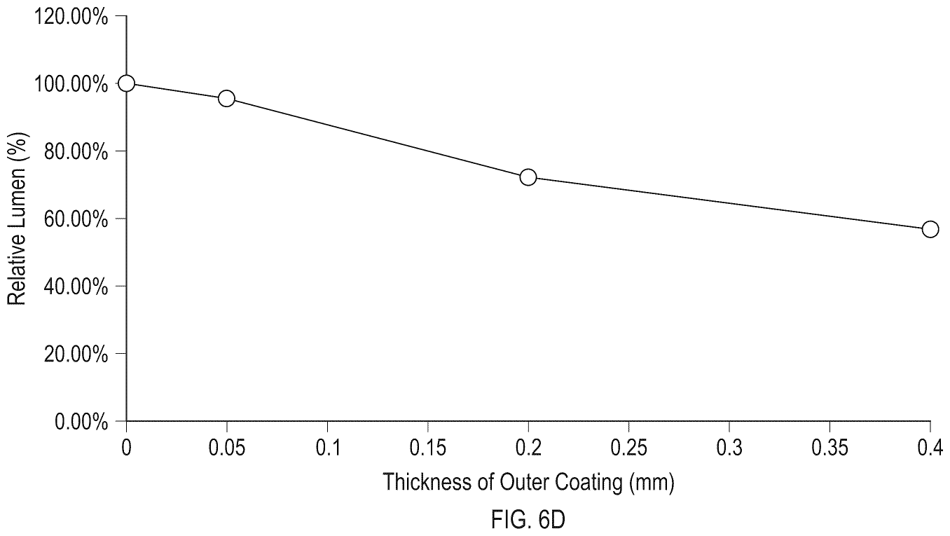

Referring to the attached drawings, FIG. 6A shows exemplary color dots of a LED light source without an outer coating and a LED light source with different thicknesses of outer coatings, where filled rectangles represent color dots of a LED light source without an outer coating; filled rhombuses represent the color dots of a LED light source with an outer coating having a thickness of 0.05 mm; filled triangles represent the color dots of a LED light source with an outer coating having a thickness of 0.2 mm; and filled circles represent the color dots of a LED light source with an outer coating having a thickness of 0.4 mm. The application of the outer coating causes the color dots to move over the blackbody trajectory and to a lower correlated color temperature (CCT), wherein the thicker the outer coating, the more significant the offset amplitudes of the color dots and color temperature.

FIG. 6B shows the color dot offset amplitude in CIE 1931 color space of the corresponding LED light source with an outer coating as the thickness of the outer coating changes. As the diameter or thickness of the outer coating increases, i.e. increasing from 0.05 mm to 0.4 mm, the color dot offset amplitude significantly increases.

FIG. 6C shows the color temperature offset amplitude of the corresponding LED light source with an outer coating as the thickness of the outer coating changes. As the diameter or thickness of the outer coating increases, i.e., increasing from 0.05 mm to 0.4 mm, there is a significant offset in the correlated color temperature (CCT).

FIG. 6D shows the changes in luminous flux of the corresponding LED light source with an outer coating as the thickness of the outer coating changes. As the diameter or thickness of the outer coating increases, i.e., increasing from 0.05 mm to 0.4 mm, the luminous flux (lumen) decreases, resulting in increased optical loss. An increase in the diameter or thickness of the outer coating can cause light diffusion and much greater optical loss.

### Comparative Example 1

A LED light source with an outer coating was provided in the same way as example 2, except that a mixture of water and silicone (water-silicone) was used instead of n-butyl acetate as the solvent, and the water-silicone was composed of 50 wt % of water and 50 wt % of silicone based on the total weight of the mixture of water and silicone.

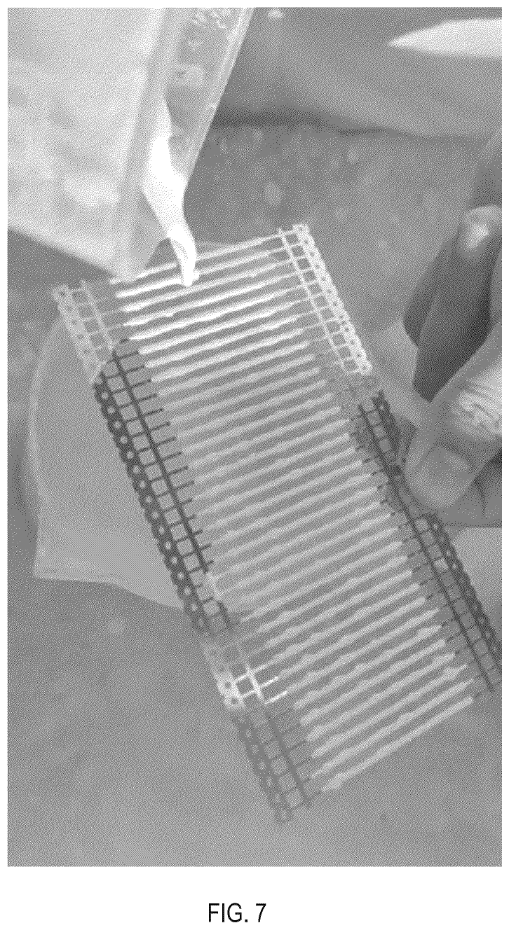

FIG. 7 shows a schematic diagram of the coating results of a coating composition prepared using water-silicone as a solvent. The results show that the coating composition based on water-silicone as a solvent has poor adhesion to the phosphor material underlying layer, making it difficult for the coating composition to adhere to the underlying material.

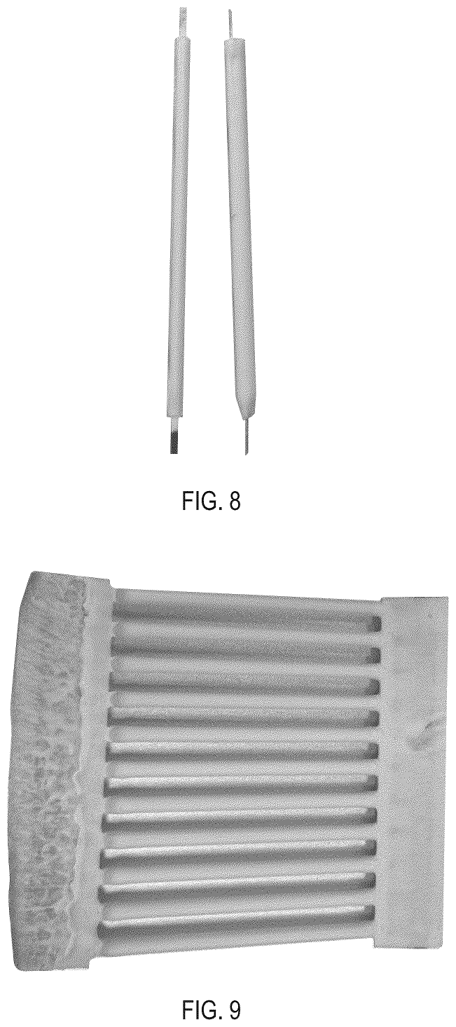

As shown in FIG. 8, the left panel represents a LED filament with an outer coating prepared when using water-silicone as a solvent to prepare the coating composition, while the right Wood IP Ref No. SAVA/603604US panel represents a LED filament with an outer coating prepared when using n-butyl acetate as a solvent to prepare the coating composition. By the comparison of the above two, it can be clearly concluded that when using water-silicone as a solvent to prepare the coating composition, the resulting LED light source with an outer coating exhibits an obviously unexpected yellow appearance. In contrast, FIG. 9 shows the LED light source prepared when using n-butyl acetate as a solvent to prepare the coating composition. As shown in FIG. 9, when n-butyl acetate is used as a solvent according to the present invention, the resulting multiple filaments exhibit the desired white appearance.

It should be noted that the terms “first”, “second”, etc. in the specification and claims of the application are used to distinguish similar objects, and they are not necessary to be used to describe a specific order or a precedence order. It should be understood that the terms used in this way can be interchanged if appropriate, so that the embodiments described here can be implemented in an order other than those described here, for example.

The above contents only describe the preferred examples of the invention, and are not intended to limit the invention. For those skilled in the art, various modifications and changes can be made to the invention. Any modifications, equivalent substitutions, improvements, and the like made within the spirit and principle of the invention shall be included within the scope of protection of the invention.

1. Alight emitting diode (LED) light source comprising:
one or more LED chips coated with a phosphor material underlying layer exhibiting a colored appearance; and
an outer coating comprising a coating composition, wherein the coating composition comprises a solvent, a binder, and a pigment, and the outer coating gives the one or more LIED chips a color appearance different from the underlying material in a power-off state.

2. The LED light source according to claim 1, wherein the solvent is an organic solvent, and the organic solvent comprises one or more of n-butyl acetate, ethyl acetate, and acetone.

3. The LED light source according to claim 1, wherein the binder comprises one or more of alkyd emulsion, vinyl acrylic resin and styrenated acrylic resin.

4. The LED light source according to claim 1, wherein the pigment comprises one or more of titanium dioxide, lutetium oxide, yttrium oxide, silicon dioxide, alumina, zirconia, quartz, and glass powder, and the pigment gives the LED chips a white appearance in a power-off state.

5. The LED light source according to claim 1, wherein the coating composition further comprises an additive.

6. The LED light source according to claim 5, wherein the additive comprises one or more of a surfactant, an antimicrobial agent, and a defoaming agent.

7. The LED light source according to claim 1, wherein the solvent is present in an amount ranging from 28 wt % to 44 wt % based on the total weight of the coating composition.

8. The LED light source according to claim 1, wherein the pigment is present in an amount ranging from 0.5 wt % to 23 wt % based on the total weight of the coating composition.

9. The LED light source according to claim 1, wherein the thickness of the outer coating ranges from 0.1 mm to 0.4 mm.

10. The LED light source according to claim 1, wherein the total thickness of the LED light source ranges from 1.2 mm to 1.8 mm.

11. A lighting device comprising one or more LED light sources, wherein the LED light source comprises:
a substrate,
one or more LED chips formed on the substrate, with the LED chip being coated with a phosphor material underlying layer exhibiting a colored appearance; and
an outer coating formed on the phosphor material underlying layer, wherein the outer coating comprises a coating composition, the coating composition comprises a solvent, a binder, and a pigment, and the outer coating gives the one or more LED chips a color appearance different from the underlying material in a power-off state.

12. The lighting device according to claim 11, wherein the solvent is an organic solvent, and the organic solvent comprises one or more of n-butyl acetate, ethyl acetate, and acetone.

13. The lighting device according to claim 11, wherein the binder comprises one or more of alkyd emulsion, vinyl acrylic resin and styrenated acrylic resin.

14. The lighting device according to claim 11, wherein the pigment comprises one or more of titanium dioxide, lutetium oxide, yttrium oxide, silicon dioxide, alumina, zirconia, quartz, and glass powder, and the pigment gives the one or more LED chips a white appearance in a power-off state.

15. The lighting device according to claim 11, wherein the coating composition further comprises an additive.

16. The lighting device according to claim 15, wherein the additive comprises one or more of a surfactant, an antimicrobial agent, and a defoaming agent.

17. The lighting device according to claim 11, wherein the solvent is present in an amount ranging from 28 wt % to 44 wt % based on the total weight of the coating composition.

18. The lighting device according to claim 11, wherein the pigment is present in an amount ranging from 0.5 wt % to 23 wt % based on the total weight of the coating composition.

19. The lighting device according to claim 11, wherein the thickness of the outer coating ranges from 0.1 mm to 0.4 mm, and the total thickness of the LED light source ranges from 1.2 mm to 1.8 mm.

20. A lamp comprising:
one or more light emitting diode (LED) light sources, each LED light source comprising:
a substrate,
one or more LED chips formed on the substrate, each LED chip being coated with a phosphor material underlying layer exhibiting a colored appearance; and
an outer coating formed on the phosphor material underlying layer, wherein the outer coating includes a coating composition, and the coating composition comprises a solvent, a binder, and a pigment.

21. Use of a coating composition comprising a solvent, a binder, and a pigment in the preparation of an outer coating of a LED light source, wherein the LED light source comprises one or more LED chips coated with a phosphor material underlying layer exhibiting a colored appearance; and the outer coating, which gives the LED chips a color appearance different from the underlying material in a power-off state.
